(19) United States
(12) Patent Application Publication
(10) Pub. No.: US 2011/0024173 A1
(43) Pub. Date: Feb. 3, 2011

(54) Ball grid array printed circuit board, package structure, and fabricating method thereof

(75) Inventors: Jin-Chang Wu, Banqiao City (TW); Wen-bing Wang, Songjiang EPZ Shanghai (CN); Xun Wang, Songjiang EPZ Shanghai (CN)

Correspondence Address: RABIN & Berdo, PC, 1101 14TH STREET, NW, SUITE 500, WASHINGTON, DC, 20005, US

(73) Assignees: Quanta Computer Inc., Tao Yuan Shien (TW); Tech-Front (Shanghai) Computer Co. Ltd., Songjiang EPZ Shanghai (CN)

(21) Appl. No.: 12/585,996

(22) Filed: Sep. 30, 2009

(30) Foreign Application Priority Data
Jul. 28, 2009 (TW) 098125399

(51) Int. Cl. H05K 1/16; H05K 1/11; H05K 3/00

(52) U.S. Cl. 174/260; 174/261; 29/843

(57) ABSTRACT

A BGA (ball grid array) printed circuit board is disclosed, which includes a substrate having a dielectric layer, a BGA pad and a solder mask formed on the dielectric layer, and an adhesive glue filled in a gap between the BGA pad and the solder mask. A BGA printed circuit board package structure and a method for fabricating the BGA printed circuit board are also disclosed.

### RELATED APPLICATIONS

This application claims priority to Taiwan Application Serial Number 98125399, filed Jul. 28, 2009, which is herein incorporated by reference.

### BACKGROUND

1. Field of Invention

The present invention relates to a ball grid array printed circuit board. More particularly, the present invention relates to a non-solder mask defined ball grid array printed circuit board.

2. Description of Related Art

Access to an electrical connection with an external circuit is required for an IC chip to function properly, and an IC device has to be packaged to prevent damage from external force or environmental factors during conveyance or pick-and-place procedures. Electronic packaging is a necessary process in integrated circuit production to allow the IC device to perform a predefined function under an organized structure and provides protection.

A ball grid array (BGA) package has been a widely used electronic package structure in integrated circuit production. The BGA package structure has plural solder balls or soldering bumps to bond the IC chip on a printed circuit board and to electrically connect conductive wires (or trace) on the printed circuit board (PCB).

Lead free process has become a consensus in recent years for environmental consciousness. However, the processing temperature in the lead free PCB process is 30-40° C. higher than the processing temperature of lead containing PCB process. Furthermore, the lead free solder ball is stiffer than conventional PbSn solder ball. Therefore, the dielectric material crack under the pad would be easily occurred.

### SUMMARY

An embodiment of the invention provides a ball grid array printed circuit board. The ball grid array printed circuit board includes a substrate having a dielectric material layer, a solder mask formed on the dielectric material layer, a ball grid array pad formed on the dielectric material layer, a gap formed between the ball grid array pad and the solder mask, and an adhesive glue filled in the gap.

Another embodiment of the invention provides a ball grid array printed circuit board package structure. The ball grid array printed circuit board package structure includes a ball grid array printed circuit board and a semiconductor device. The ball grid array printed circuit board includes a substrate having a dielectric material layer, a solder mask formed on the dielectric material layer, a ball grid array pad formed on the dielectric material layer, a gap formed between the ball grid array pad and the solder mask, and an adhesive glue filled in the gap. The semiconductor device includes a solder ball connected to the ball grid array pad.

Another embodiment of the invention provides a method for fabricating a ball grid array printed circuit board. The method includes providing a substrate comprising a dielectric material layer, and then a ball grid array pad and a solder mask are formed on the dielectric material layer. There is a gap between the ball grid array pad and the solder mask. Then, an adhesive glue is filled in the gap.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A to FIG. 1H illustrate schematic diagrams of different steps of an embodiment of the method for fabricating a ball grid array printed circuit board of the invention;

FIG. 2 illustrates a schematic diagram of an embodiment of the ball grid array printed circuit board of the invention; and

FIG. 3 illustrates a schematic diagram of an embodiment of the ball grid array printed circuit board package structure of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

The dielectric material layer under the grid ball array (BGA) pad may be easily cracked in the conventional lead free BGA printed circuit board process. The applicant found that those cracks of the dielectric material layers have a similar trend, which is started at the gap between the BGA pad and the solder mask, so that the applicant believed that the bonding strength between the dielectric material layer and the BGA pad at the gap is weaker than other (or have to be enhanced).

The present embodiments provide a ball grid array printed circuit board to enhance the bonding strength between the dielectric material layer and the BGA pad at the gap.

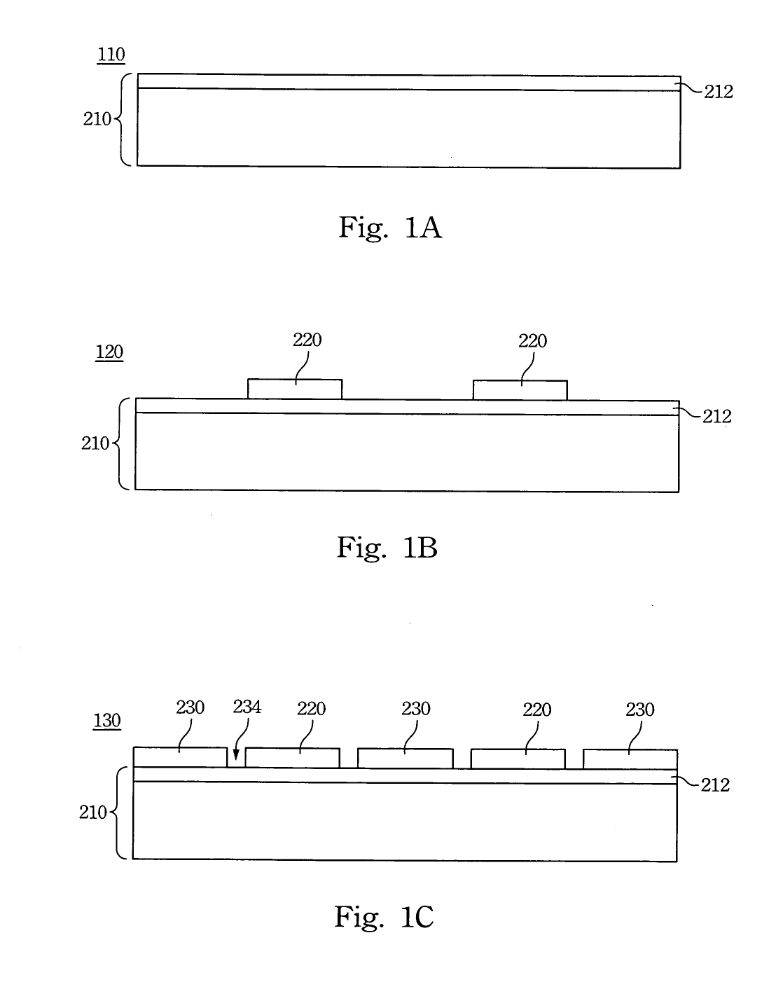

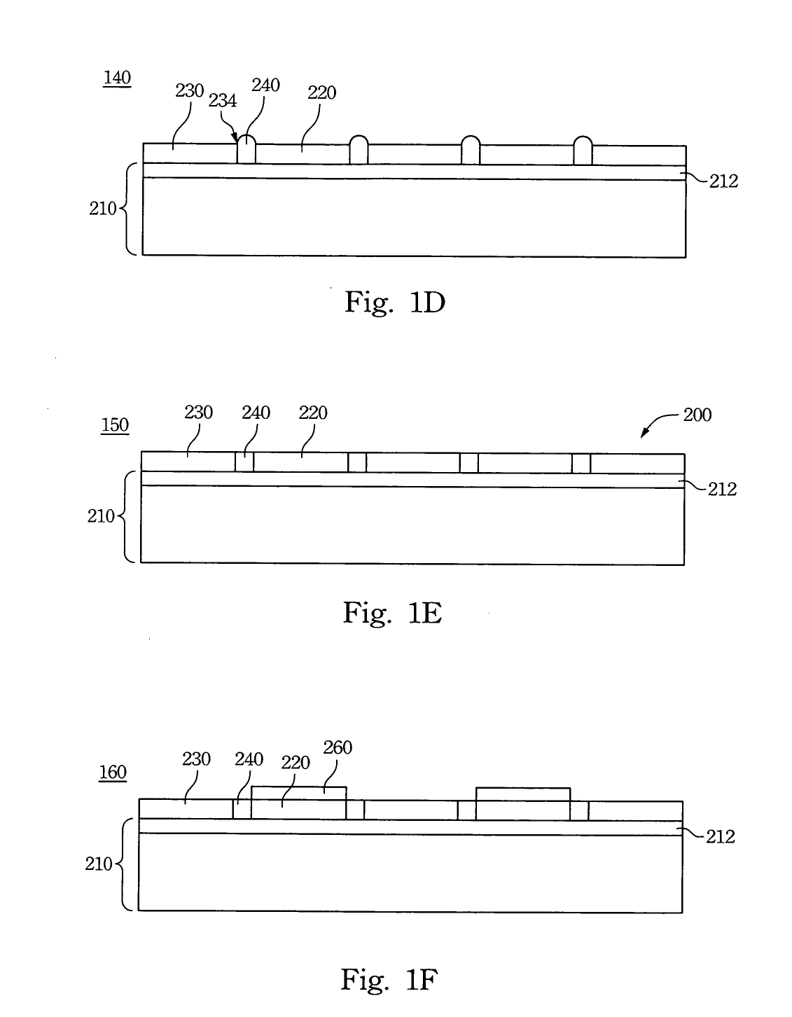

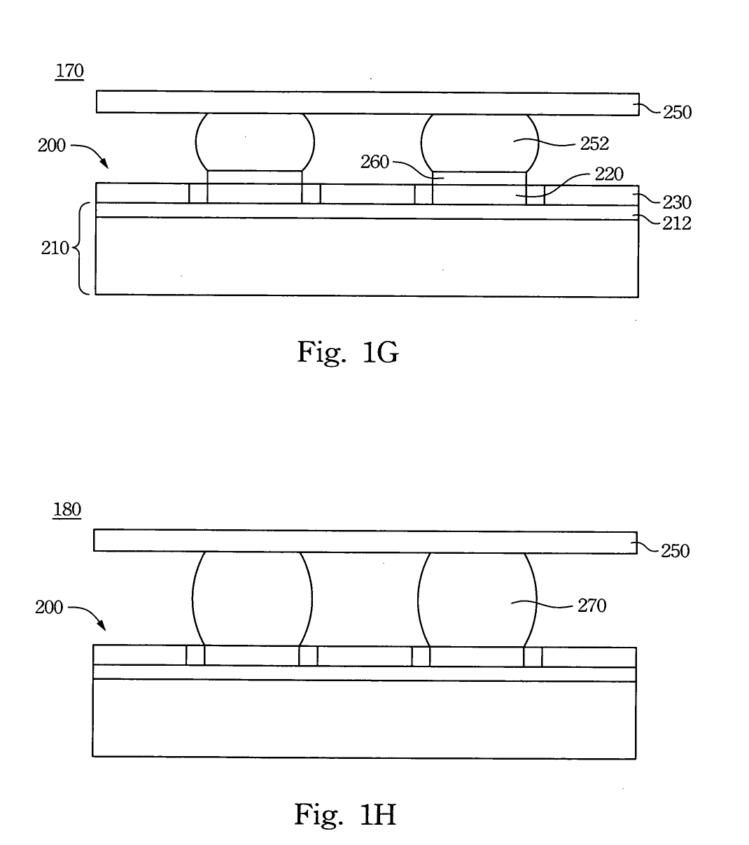

Refer to FIG. 1A to FIG. 1H. FIG. 1A to FIG. 1H illustrate schematic diagrams of different steps of an embodiment of the method for fabricating a ball grid array printed circuit board of the invention. As shown in FIG. 1A, a substrate 210 is provided in step 110. The substrate 210 has a dielectric material layer 212. Then, referring to FIG. 1B, at least one ball grid array pad 220 is formed on the dielectric material layer 212 in step 120.

Referring to FIG. 1C, a solder mask 230 is formed on the dielectric material layer 212 in step 130, and there is a gap 234 formed between the solder mask 230 and the BGA pad 220.

Referring to FIG. 1D, an adhesive glue 240 is provided or injected into the gap 234 between the BGA pad 220 and the solder mask 230 in step 140. The step 140 further includes solidifying the adhesive glue 240. Then, referring to FIG. 1E, the adhesive glue 240 is flattened in step 150. A part of the adhesive glue 240 higher then the BGA pad 220 is removed in step 150 to uniform the surface. Finally, a BGA printed circuit board 200 is completed, wherein the adhesive glue 240 is filled in the gap 234 between the BGA pad 220 and the solder mask 230.

The BGA printed circuit board 200 in this embodiment is a non-solder mask defined (NSMD) type. The solder mask 230 is arranged around the BGA pad 220 in the NSMD BGA printed circuit board 200 to protect the surface of the dielectric material layer 212 and to prevent the semiconductor device from bonding on the incorrect location of the printed circuit board 200. The material of the solder mask 230 is an insulating material, such as a flux.

The adhesive glue 240 can be an epoxy resin or a UV adhesive. The adhesive glue 240 is heated to be solidified in step 140 when the material of the adhesive glue 240 is epoxy resin. The adhesive glue 240 is ultraviolet radiated to be solidified in step 140 when the material of the adhesive glue is UV adhesive.

The adhesive glue 240 is filled in the gap 234 between the BGA pad 220 and the solder mask 230. The adhesive glue 240 bonds with the dielectric material layer 212 and the also bonds with the edge of the BGA pad 220, so that the bonding force between the BGA pad 220 and the dielectric material layer 212 can be enhanced. The BGA pad 220, the adhesive glue 240, and the solder mask 230 become a continuous structure and share the stress in the package process, so that the stress would not be easily conducted to the dielectric material layer 212 via the gap 234 and the risk of cracks for the dielectric material layer 212 can be reduced.

The embodiment of the invention further includes step 160 to step 180, which are disclosed in FIG. 1F to FIG. 1H to electrically connect the semiconductor device 250 to the BGA printed circuit board 200 by a surface mounting technology (SMT).

Referring to FIG. 1F, a solder paste 260 is applied on the BGA pad 220 in step 160. Then in FIG. 1G, the semiconductor device 250 having a solder ball 252 is placed on the BGA pad 220 in step 170. The semiconductor device 250 can be fastened on the BGA printed circuit board 200 temporarily with the solder paste 260. Finally, in FIG. 1H, the solder ball 252 of the semiconductor device 250 is combined with the solder paste 260 to form a solder joint 270 by a reflow process in step 180. The semiconductor device 250 is fixed on the BGA printed circuit board 200 by the solder joint 270.

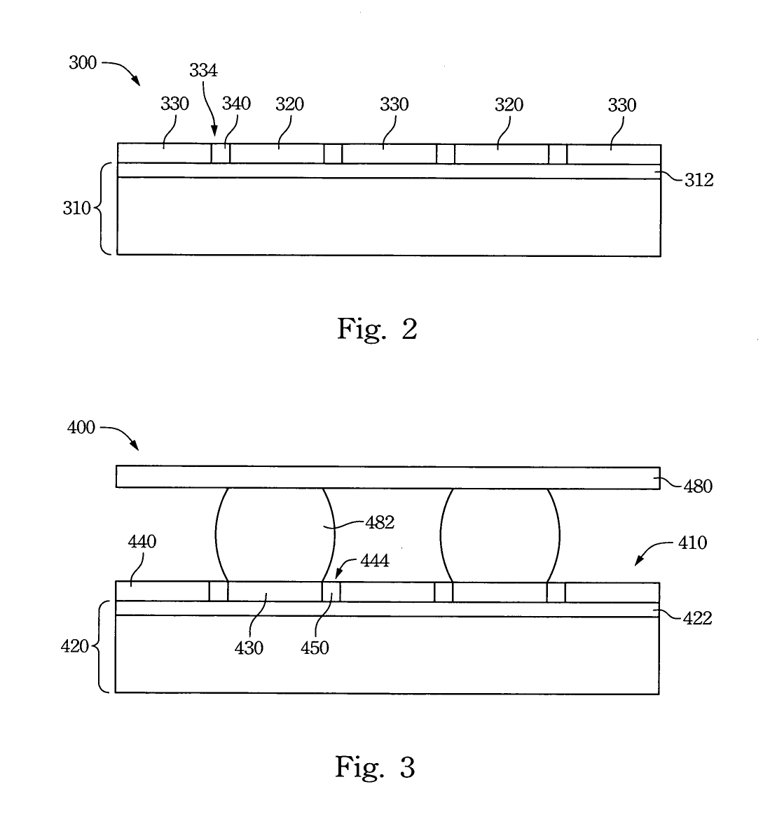

Refer to FIG. 2. FIG. 2 illustrates a schematic diagram of an embodiment of the ball grid array printed circuit board of the invention. The BGA printed circuit board 300 includes the substrate 310 having the dielectric material layer 312, the BGA pad 320 formed on the dielectric material layer 312, the solder mask 330 formed on the dielectric material layer 312. There is a gap 334 between the BGA pad 320 and the solder mask 330. The BGA printed circuit board 300 further includes the adhesive glue 340 filled in the gap 334 between the BGA pad 320 and the solder mask 330.

The solder mask 330 can be a flux. The adhesive glue 340 can be epoxy resin or UV adhesive. The substrate 310 can be a FR4 board. There are plural vias (not shown) arranged under the BGA pad 320.

The gap 334 between the BGA pad 320 and the solder mask 330 is filled by the adhesive glue 340. The adhesive glue 340 bonds with the dielectric material layer 312 and also bonds with the edge of the BGA pad 320, so that the bonding force between the BGA pad 320 and the dielectric material layer 312 is enhanced. The BGA pad 320, the adhesive glue 340, and the solder mask 330 become a continuous structure and share the stress in the package process, so that the stress would not be easily conducted to the dielectric material layer 312 via the gap 334 and the risk of cracks for the dielectric material layer 312 can be reduced.

Refer to FIG. 3. FIG. 3 illustrates a schematic diagram of an embodiment of the BGA printed circuit board package structure of the invention. The BGA printed circuit board package structure 400 includes the BGA printed circuit board 410 and the semiconductor device 480. The BGA printed circuit board 410 includes the substrate 420 having the dielectric material layer 422, the BGA pad 430 formed on the dielectric material layer 422, the solder mask 440 formed on the dielectric material layer 422. There is a gap 444 between the BGA pad 430 and the solder mask 440. The BGA printed circuit board 410 further includes the adhesive glue 450 filled in the gap 444 between the BGA pad 430 and the solder mask 440. The semiconductor device 480 has the solder ball 482 connected to the BGA pad 430 to electrically connect the semiconductor device 480 and the BGA printed circuit board 410.

The semiconductor device 480, for example, is a surface mounting device. The semiconductor device 480 is fixed on the BGA printed circuit board 410 by a surface mounting process. The solder ball 482 of the semiconductor device 480 would become the solder joint to fix the semiconductor device 480 on the BGA printed circuit board 410. The material of the solder ball 482 is Tin. The solder ball 482 does not touch the BGA printed circuit board 410 in this embodiment.

According to the disclosed embodiments, the gap between the BGA pad and the solder mask is filled by the adhesive glue. The adhesive glue bonds with the dielectric material layer and also bonds with the edge of the BGA pad, so that the bonding force between the BGA pad and the dielectric material layer is enhanced. The BGA pad, the adhesive glue, and the solder mask become a continuous structure and share the stress in the package process, so that the stress would not be easily conducted to the dielectric material layer via the gap and the risk of dielectric material layer cracks can be reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A ball grid array printed circuit board comprising:
a substrate comprising a dielectric material layer;
a solder mask formed on the dielectric material layer;
a ball grid array pad formed on the dielectric material layer;
a gap formed between the ball grid array pad and the solder mask; and
an adhesive glue filled in the gap.

2. The ball grid array printed circuit board of claim 1, wherein the solder mask comprises a flux.

3. The ball grid array printed circuit board of claim 1, wherein the adhesive glue comprises epoxy resin.

4. The ball grid array printed circuit board of claim 1, wherein the adhesive glue comprises UV adhesive.

5. The ball grid array printed circuit board of claim 1, wherein the ball grid array printed circuit board is a non-solder mask defined ball grid array printed circuit board.

6. A ball grid array printed circuit board package structure comprising:
a ball grid array printed circuit board comprising:
a substrate comprising a dielectric material layer;
a solder mask formed on the dielectric material layer;
a ball grid array pad formed on the dielectric material layer;
a gap formed between the ball grid array pad and the solder mask; and
an adhesive glue filled in the gap; and
a semiconductor device comprising a solder ball connected to the ball grid array pad.

7. The ball grid array printed circuit board package structure of claim 6, wherein the solder mask comprises a flux.

8. The ball grid array printed circuit board package structure of claim 6, wherein the adhesive glue comprises epoxy resin.

9. The ball grid array printed circuit board package structure of claim 6, wherein the adhesive glue comprises UV adhesive.

10. The ball grid array printed circuit board package structure of claim 6, wherein the solder ball does not touch the adhesive glue.

11. The ball grid array printed circuit board package structure of claim 6, wherein the material of the solder ball is Tin.

12. The ball grid array printed circuit board package structure of claim 6, further comprising a solder paste disposed on the ball grid array pad, wherein the solder paste is combined with the solder ball, thereby a solder joint is formed to connect the semiconductor device to the ball grid array pad.

13. A method for fabricating a ball grid array printed circuit board, the method comprising:
providing a substrate comprising a dielectric material layer;
forming a ball grid array pad on the dielectric material layer;
forming a solder mask on the dielectric material, wherein there is a gap between the ball grid array pad and the solder mask; and
filling an adhesive glue in the gap.

14. The method for fabricating a ball grid array printed circuit board of claim 13, wherein the step of filling an adhesive glue in the gap comprising:
injecting an adhesive glue into the gap;
solidifying the adhesive glue; and
flattening the adhesive glue.

15. The method for fabricating a ball grid array printed circuit board of claim 14, wherein the step of solidifying the adhesive glue comprises heating the adhesive glue.

16. The method for fabricating a ball grid array printed circuit board of claim 14, wherein the step of solidifying the adhesive glue comprises ultraviolet radiating the adhesive glue.

17. The method for fabricating a ball grid array printed circuit board of claim 13, wherein the adhesive glue comprises epoxy resin.

18. The method for fabricating a ball grid array printed circuit board of claim 13, wherein the adhesive glue comprises UV adhesive.

19. The method for fabricating a ball grid array printed circuit board of claim 13, wherein the solder mask comprises a flux.

20. The method for fabricating a ball grid array printed circuit board of claim 13, the ball gird array printed circuit board is a non-solder mask defined ball grid array printed circuit board.
